(19) United States
(12) Patent Application Publication
(10) Pub. No.: US 2026/0043645 A1
(43) Pub. Date: Feb. 12, 2026

(54) Capacitive Height Sensing with Variable Step Charge-to-Voltage Converter

(71) Applicant: Avago Technologies International Sales Pte. Limited, Singapore (SG)

(72) Inventor: Kin Wai Roy Chew, Singapore (SG)

(21) Appl. No.: 19/343,925

(22) Filed: Sep. 29, 2025

Related U.S. Application Data
(63) Continuation-in-part of application No. 18/499,119, filed on Oct. 31, 2023, now Pat. No. 12,451,158.

(51) Int. Cl. G01B 7/06; G01R 19/165; G01R 19/25; G11B 5/48; H02J 7/34

(52) U.S. Cl. CPC G01B 7/082; G01R 19/16576; G01R 19/2503; G11B 5/4826; H02J 7/345; H02J 2207/50

(57) ABSTRACT

Solutions for capacitive height sensing (CHS) can include a multi-phase charge-to-voltage (C2V) converter. In some examples, a measurement cycle may begin with a coarse phase using a first voltage step and transition to a fine phase using a second, smaller voltage step. Control logic can be configured to manage the voltage steps and integrate charge from a variable capacitor associated with a head gimbal assembly (HGA). In some embodiments, an offset circuit may be used to increase measurement sensitivity. An output signal based on the integrated voltage may be indicative of the HGA's height.

### CROSS-REFERENCE TO RELATED APPLICATIONS

This application is a continuation in part of U.S. patent application Ser. No. 18/499,119 (the “'119 application”), titled “Head Gimbal Assembly Height Determination with Charge-to-Voltage Converter,” (attorney docket no. 5009.230132US01), filed Oct. 31, 2023, by Chew, the disclosure of which is incorporated herein for all purposes.

This application may be related to U.S. patent application Ser. No. ______, titled “Capacitive Height Sensing with Time-to-Digital Converter,” (attorney docket no. 5009.250209US01), filed on a date even herewith by Chew, the disclosure of which is incorporated herein for all purposes.

### FIELD

This disclosure relates in general to semiconductor circuits and more particularly to circuits and methods for capacitive height sensing in data storage devices.

### BACKGROUND

The height of a head gimbal assembly (HGA) in a hard disk drive (HDD) is typically measured as a function of the capacitance that is formed between the HGA and the underlying magnetic media. As the HGA gets closer to the disk, this capacitance increases. This process, known as capacitive height sensing (CHS), is used to determine the proximity of the HGA to the platter to avoid contact and ensure reliable operation. However, the change in capacitance is very small, often less than 1.5% of the total baseline capacitance, making it difficult to measure accurately, especially in the presence of process, voltage, and temperature (PVT) variations.

Some approaches to CHS often utilize a relaxation oscillator, where the HGA capacitance is part of the oscillator circuit. Changes in capacitance result in changes to the oscillation period, which can be measured. While functional, relaxation oscillators are sensitive to PVT variations and comparator jitter. Furthermore, to achieve the high resolution needed to detect the small capacitance changes, a long measurement or “dwell” time is required, which can lead to increased wear on the head.

An alternative approach, described in the parent application, uses a charge-to-voltage (C2V) converter. This method is less sensitive to timing and PVT variations. However, a C2V converter that uses a single, constant voltage step for charging the HGA capacitance presents a fundamental trade-off between measurement speed and resolution. A small, precise voltage step provides high resolution but requires many steps, resulting in a long measurement time. Conversely, a large voltage step is faster but sacrifices resolution. Thus, there is a need for an improved CHS circuit that can achieve both high speed and high precision.

### BRIEF DESCRIPTION OF THE DRAWINGS

FIG. 1 is a block diagram of a system comprising a control system for an HGA CHS, in accordance with some embodiments.

FIGS. 2A and 2B are detailed schematic drawings illustrating circuits comprising a C2V, in accordance with some embodiments.

FIG. 3 is a timing diagram illustrating a two-phase measurement cycle, in accordance with some embodiments.

FIG. 4 is a flow diagram illustrating a method of measuring an HGA height, in accordance with some embodiments.

FIG. 5 is a block diagram illustrating an example hardware implementation of control logic, in accordance with some embodiments

### DETAILED DESCRIPTION

Some embodiments provide improved techniques for measuring HGA height in a HDD. As described in the incorporated '119 application, the height of the HGA affects the capacitance (C_{hga}) that is formed between the HGA and the media. As the HGA gets closer to the disk, C_{hga} increases. Typically, HGA height can be determined by measuring this change in capacitance, (C_{delta}), using capacitive height sensing (CHS). However, because C_{delta} is very small (e.g., <1.5% of C_{hga}), it is difficult to measure these small changes reliably across process, voltage, and temperature (PVT) variations.

Some approaches to CHS often utilize a relaxation oscillator, where C_{hga} is charged and discharged continuously. As C_{hga} increases, the oscillation period increases. While this allows for measurement, relaxation oscillators are sensitive to PVT variations and comparator jitter, and they require a long dwell time to achieve high resolution, which can increase head wear.

To address these issues, the '119 application introduced an improved architecture based on a C2V convertor. By utilizing a C2V converter, a CHS circuit becomes less sensitive to timing and PVT variations. However, a C2V converter that uses a single, constant voltage step for charging presents a trade-off between measurement speed and resolution.

Various embodiments described herein solve this problem by employing a multi-phase “measurement cycle” within a single measurement operation. In some embodiments, the measurement process begins with a first phase, which can be referred to as a “coarse measurement phase,” and transitions to a second phase, which can be referred to as a “fine measurement phase.” This multi-phase approach provides an advantageous balance of speed and precision, significantly reducing the overall measurement time without compromising accuracy, which in turn can reduce wear on the head. While exemplary embodiments are described in the context of data storage devices, various embodiments and the principles and techniques thereof can be applied to and/or employed by any system requiring high-speed, high-precision capacitive proximity or distance sensing, including without limitation microelectromechanical systems (MEMS), semiconductor manufacturing and inspection equipment, and precision robotics.

As used herein, the term “charge-to-voltage converter” refers broadly to a circuit, such as a discrete-time switched-capacitor integrator, that converts an amount of charge stored in a capacitor into a proportional voltage. A “measurement cycle” refers broadly to the complete process for a single HGA height measurement. A “coarse measurement phase” refers broadly to an initial part of the measurement cycle where a larger voltage step is used for rapid, lower-resolution measurement, while a “fine measurement phase” refers broadly to a subsequent part of the measurement cycle where a smaller, more precise voltage step is used.

### Exemplary Embodiments

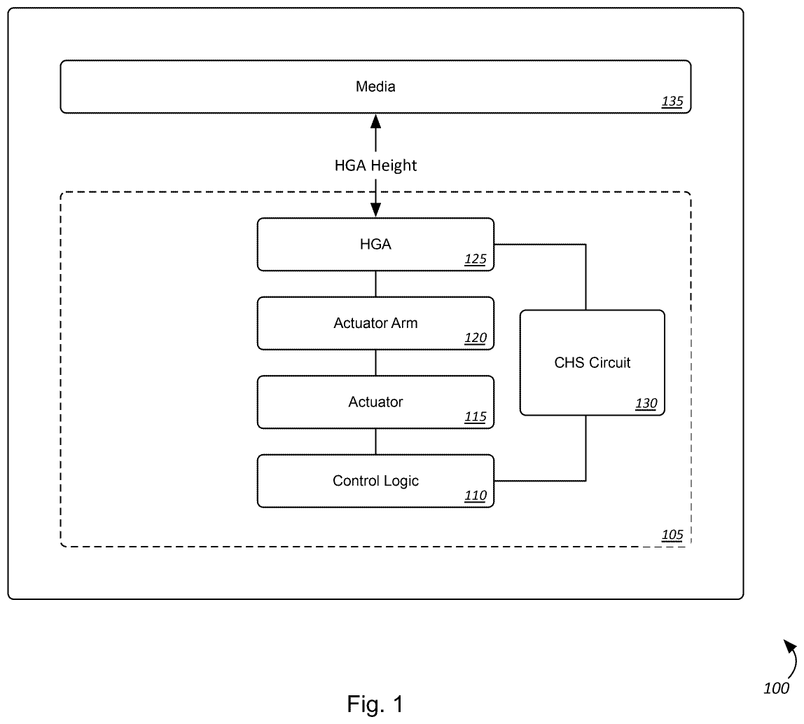

FIG. 1 is a schematic block diagram of an exemplary system 100 in which the disclosed technology can be implemented. In some embodiments, the system 100 can be a data storage device, such as a hard disk drive (HDD). The system 100 can include a control system 105 configured to control a head stack assembly (HSA) of the HDD. The HSA is the moving assembly that positions the HGA 125 over the magnetic media 135 and can include, without limitation, the actuator arm 120, the actuator 115, a preamplifier, and a flex cable. The control system 105 can include control logic 110, an actuator 115, an actuator arm 120, a head gimbal assembly (HGA) 125, and a CHS circuit 130. The system 100 further includes a magnetic media 135, such as a hard disk drive platter. In various examples, the actuator 115 may include, without limitation, a voice coil actuator (e.g., a permanent magnet and wire coil actuator), moving magnet actuator, shaped memory alloy (SMA) actuator, piezoelectric, thermal, or other suitable actuators. The actuator 115 may be configured to cause the actuator arm 120 to move. actuator arm 120 may be coupled to the actuator 115 via a pivot bearing or other swage connection, at a first end (e.g., a proximal end). The HGA 125 may, in turn, be coupled to an opposite end of the actuator arm 120 (e.g., a distal end of the actuator arm 120, away from the connection to the actuator 115). In various examples, the HDD may include one or more platters. A respective actuator arm 120 and respective HGA 125 may be disposed on (e.g., over) and/or disposed under (e.g., below) each respective platter of the one or more platters.

While a single HGA 125 and magnetic media 135 are shown for clarity, it is to be understood that a system 100 can include a plurality of magnetic media platters and a corresponding plurality of HGAs, and the disclosed systems and methods can be applied to any or all of them. In various examples, the control logic 110 can be configured to generate a control signal to drive the actuator 115, which in turn causes movement of the actuator arm 120 to adjust the vertical position of the HGA 125. In some examples, the control logic 110 may be configured to control an elevator function (e.g., vertical position control) of the HGA 125 via up and/or down movement of the actuator arm 120. The position of the HGA 125 can be determined by the CHS circuit 130 and provided as feedback to the control logic 110 for further adjustments.

The CHS circuit 130 can be implemented as any of the exemplary circuits described in more detail in the subsequent figures. The control logic 110, as well as the local control logic described in subsequent figures, can be implemented in a variety of ways. The term, “logic,” is used herein to refer broadly to any tangible representation of the techniques, principles, and/or methodologies that govern the behavior of electronic components and systems to perform and/or achieve specific operations. Logic can include a wide array of elements including software instructions, firmware instructions, and/or hardware instructions, circuitry, and/or configurations.

The logic (and/or the instructions embodying the logic) collectively can instruct and/or cause such electronic components and/or systems how to process information and/or execute tasks. In the embodiments described herein, the control logic 110 is typically implemented as hardware or firmware circuitry, although this is not required of all embodiments. The term, “circuitry,” is used broadly herein to refer to any tangible arrangement of electronic components, including hardware and/or firmware, configured to perform one or more of the functions described herein. Examples of such circuitry might be embodied by a semiconductor chip, a system on a chip (SoC), an application-specific integrated circuit (ASIC), a programmable logic device (e.g., a field-programmable gate array (FPGA)), and/or the like. Examples of such circuitry can include, without limitation, one or more of a semiconductor chip, system on a chip (SoC), application-specific integrated circuit (ASIC), programmable logic devices (e.g., field-programmable gate arrays (FPGA)), and/or the like. Thus, some or all of the logic enabling or causing the performance of some or all of the operations described herein might be encoded in hardware or firmware circuitry and executed directly by such circuitry.

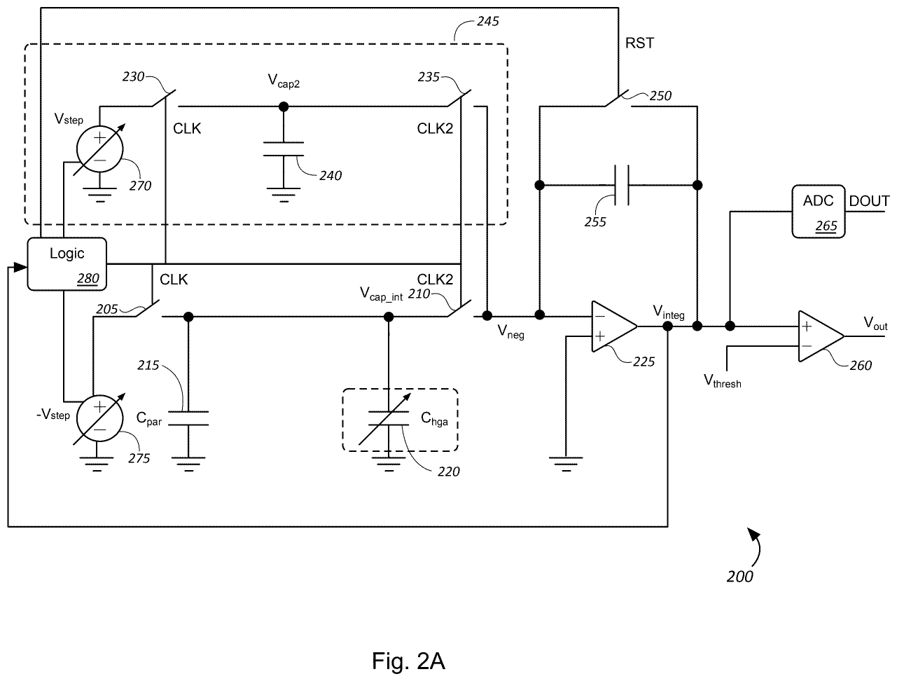

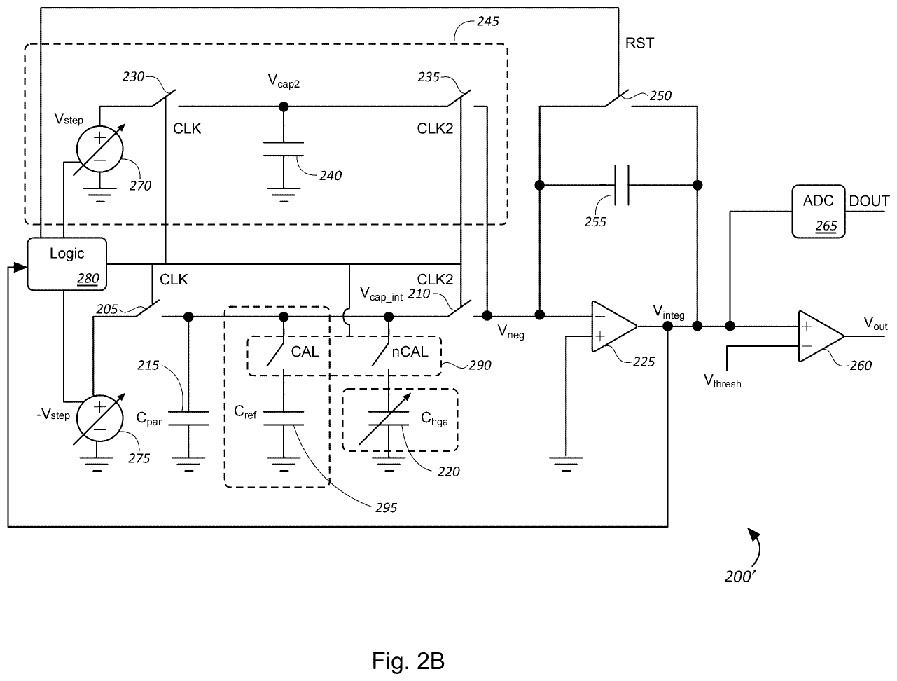

FIG. 2A is a schematic diagram of a circuit 200 that is an exemplary embodiment of a CHS circuit employing a multi-phase C2V converter. The circuit 200 can be used as the CHS circuit 130 of FIG. 1. The circuit 200 includes a main charge transfer path coupled to a variable capacitor 220. As used herein, the term “variable capacitor” refers to the inherent physical capacitance (C_{hga}) formed between the head gimbal assembly (HGA) and the media, the value of which changes as a function of the height between the two. In various examples, the C_{hga} might be measured at a signal pad of the HGA. A pad, as used herein, refers to a signal pad of a circuit, such as, without limitation, an input/output pad, attenuating pad, or other conductive structure within the circuit from which a signal may be measured or input.

The circuit also shows a parasitic capacitance (Cpar) 215, which represents the unwanted but unavoidable capacitance that arises from the physical layout of the circuit, such as from the metal traces on the circuit board and the input pins of the amplifier 225. Both the main path and an offset circuit 245 provide charge to an integrator formed by an amplifier 225 and a filter capacitor 255. In operation, the charge-to-voltage converter subcircuit can be an integrator, in which the amplifier 225 outputs a voltage (vinteg), that is proportional to the integrated value of the total charge applied to its inverting input. The term, “offset circuit,” is used broadly herein to refer to any subcircuit that improves the accuracy or precision of a HGA height measurement by offsetting any value (e.g., capacitance) on which that measurement is based. One example of an offset circuit is the offset circuit 245 (described in further detail below), which removes a fixed amount of charge from the variable capacitor during each charging cycle to improve measurement sensitivity, but embodiments are not limited to any specific design of offset circuit.

The integrator's output, the analog voltage V_{integ}, is provided to one or more output components, such as a comparator 260 or an optional analog-to-digital converter (ADC) 265. The comparator 260 compares the V_{integ} signal to a final (or reference) threshold voltage, Vₜₕᵣₑₛₕ, and produces a binary digital output signal, Vₒᵤₜ. For example, Vₒᵤₜ can be a logic high when V_{integ} exceeds Vₜₕᵣₑₛₕ and a logic low otherwise. This provides a simple binary indication of whether the HGA has crossed a certain height threshold. The ADC 265, in some embodiments, can convert the analog V_{integ} signal into a multi-bit digital value, DOUT, which provides a more granular measurement of the HGA height. The control logic 280 can then correlate the output signal (Vₒᵤₜ or DOUT) to a physical height measurement, for example by using a pre-calibrated lookup table or a formula. A reset switch 250 is coupled across the filter capacitor 255 to reset the integrator between measurements. The terms “reference threshold voltage” and “final threshold voltage” refer to to a voltage level that, when exceeded by the integrated voltage, indicates the completion of a measurement cycle, often corresponding to a specific HGA height or event.

The circuit's operation is driven by two or more non-overlapping clock signals (e.g., CLK and CLK2). The main path includes a first switch 205 and a second switch 210 controlled by these clocks. The offset subcircuit 245 includes a third switch 230, a fourth switch 235, and an offset capacitor 240. The primary purpose of the offset subcircuit 245 is to increase the sensitivity of the measurement. Because the change in HGA capacitance (C_{delta}) is very small compared to the total baseline capacitance (C_{hga}), the offset capacitor 240 is used to subtract a fixed amount of charge during each cycle. This fixed charge is chosen to cancel out the baseline charge from both the nominal C_{hga} and the parasitic capacitance 215. By removing this large, static offset, the integrator's output V_{integ} becomes much more sensitive to the small changes in charge caused by C_{delta}.

The multi-phase operation is enabled by one or more variable voltage sources 270 and 275 and control logic 280. The term “variable voltage source” is used broadly herein to refer to any component or subsystem that can produce multiple, distinct voltage levels (referred to as Vₛₜₑₚ and −Vₛₜₑₚ, respectively, on FIG. 2A and elsewhere herein) in response to a control signal. Examples of variable voltage sources can include, but are not limited to, digital-to-analog converters (DACs) controlled by logic (e.g., the control logic 280, programmable voltage regulators, or other similar circuitry). For example, in some embodiments, the control logic 280 receives a feedback signal from the output of the amplifier 225, allowing it to sample the integrated voltage (V_{integ}). In operation, the amplifier 225 and filter capacitor 255 generate the output voltage V_{integ}, which is proportional to the total charge accumulated at the inverting input (V_{neg}). During each clock cycle, charge is transferred in a two-phase operation. The change in the output voltage (V_{delta}) after a number of cycles (n) is directly proportional to the change in the HGA capacitance (C_{delta}). For example, the change in C_{hga} may be determined as a function of V_{delta}, e.g., using the relationships disclosed in the '119 application, while V_{delta} itself can be determined based, at least in part, on the output of the comparator 260, Vₒᵤₜ, and/or the digital output of the ADC 265, DOUT. In some examples, the output of the comparator 260 can indicate, for example, whether a change in the height of the HGA has exceeded a threshold distance (e.g., whether the HGA has moved by a threshold magnitude). In other examples, the output of the ADC 265, DOUT, might be indicative of a change in height of the HGA. Alternatively, DOUT might be associated with the position of the HGA. The sensitivity of the measurement can be increased by accumulating charge over a larger number of cycles (n), using a larger voltage step, or a smaller filter capacitor 255.

The control logic 280 orchestrates the multi-phase measurement. It begins in a coarse phase by controlling the variable voltage sources 270 and 275 to provide a large voltage step, causing V_{integ} to ramp up quickly. Based on the occurrence of a transition condition, the control logic 280 transitions to a fine phase, controlling the voltage sources to provide a smaller voltage step for higher resolution. The term, “transition condition” is used broadly herein to refer any circumstance or event that causes the CHS to transition from one measurement phase to a subsequent measurement phase. Examples of a transition condition occurring can include without limitation, performance in the current measurement phase a number charge-discharge cycles meeting or exceeding a cycle count, V_{integ} crossing a preliminary threshold for the current measurement phase, and/or the like. While the exemplary embodiments herein describe a two-phase (coarse and fine) measurement, it is to be understood that the measurement cycle could comprise three or more phases, each of which (other than the first phase) having its own transition condition, and, in some cases, each using progressively smaller voltage steps to further optimize the balance between speed and precision. The final V_{integ} is then used by the comparator 260 or ADC 265 to generate an output indicative of the HGA height.

FIG. 2B is a schematic diagram of a CHS circuit 200′ in accordance with another set of embodiments. The circuit 200′ employs a C2V converter similar to that of FIG. 2A and illustrates additional features that can be included in some embodiments to provide in situ calibration of the CHS The components in circuit 200′ that have like-numbered counterparts in circuit 200 can be similar in structure and function to those described above. The circuit 200′ further comprises an input selection switch 290 and a reference capacitor 295. These features, which can be included individually or in combination depending on the embodiment, can provide additional robustness and accuracy.

The input selection switch 290 and reference capacitor 295 provide an in-situ calibration mechanism to improve measurement accuracy against drift from PVT variations or circuit aging.

In some embodiments, the circuit can be operated in a calibration mode. In such a mode, the control logic 280 can operate the input selection switch 290 to substitute the known, stable reference capacitor 295 for the variable capacitor 220. The measurement method is then executed on this reference capacitor to obtain a reference measurement. This calibration measurement can be performed one or more times, for example, before or between actual HGA height measurements. The result of the calibration measurement can then be used by the control logic 280 to calculate a correction factor to account for any drift in the circuit's components, ensuring the subsequent measurements of the HGA height are more accurate.

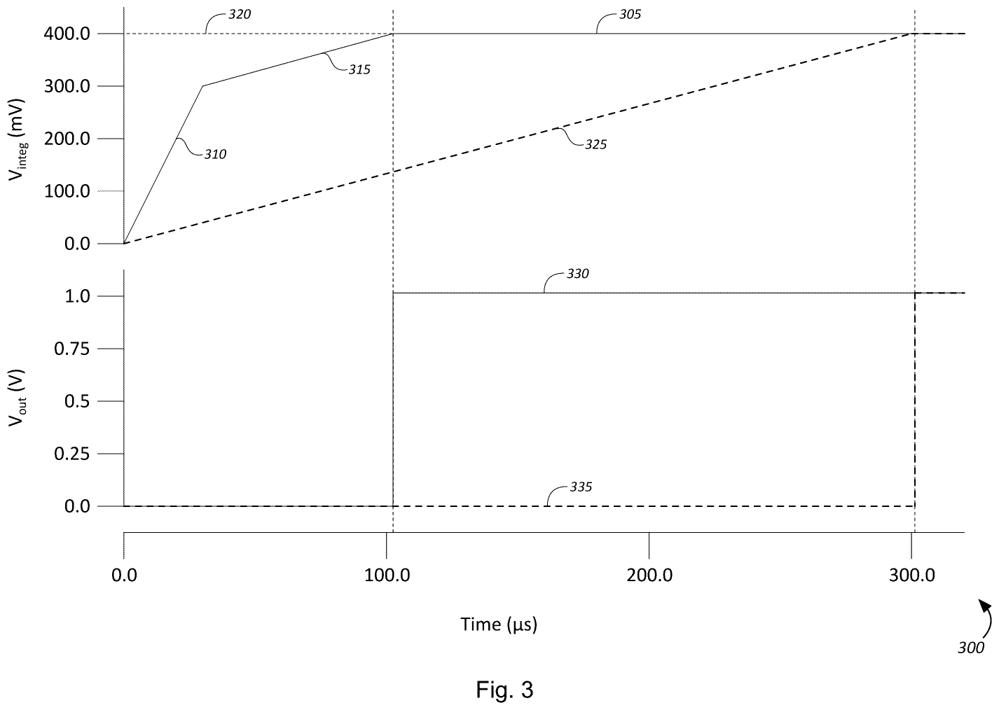

FIG. 3 is a timing diagram 300 that illustrates the operation of a multi-phase C2V converter, such as the circuit 200 of FIG. 2A. The diagram shows two plots: the upper plot shows the integrated voltage (V_{integ}) versus time, and the lower plot shows the corresponding binary output signal (Vₒᵤₜ) versus time. In both plots, the solid line represents values measured using the multi-phase approach, while the dashed line represents values from a fixed-step approach for comparison.

The solid line 305 shows the V_{integ} signal for the multi-phase method. The measurement begins with a coarse phase 310, where a large voltage step (V_{step_large}) is used. This results in a much steeper slope, allowing the V_{integ} signal to ramp up quickly. At a transition point, the control logic transitions the circuit to a fine phase 315. In this phase, a smaller voltage step (V_{step_small}) is used, resulting in a shallower slope that allows for a high-resolution final measurement.

In some embodiments, V_{step_large} can be an integer multiple of V_{step_small}. For example, as illustrated, the coarse voltage step can be eight times the fine voltage step. The control logic 280 can determine the transition point based on an estimated target number of steps. This estimation can be done, for example, by performing a very brief initial measurement (e.g., a single coarse step), sampling the resulting V_{integ}, and extrapolating the total number of fine steps that will be needed to reach the final threshold, Vₜₕᵣₑₛₕ 320. Based on this estimate, the control logic can calculate the transition point. Merely by way of example, if the control logic estimates that the target step count is 260, it might set the transition point to occur at 240 fine-step-equivalents. This means the first 30 coarse steps (which are equivalent to 240 fine steps) are performed in the coarse phase, and the final ^{˜}20 steps are performed in the fine phase.

In contrast, the dashed line 325 represents the V_{integ} signal that would be produced by a C2V converter using a single, small, constant voltage step (equal to V_{step_small}), for example as disclosed in the '119 application. While this method is precise, it is also relatively slow, taking approximately 322 us to reach the same Vₜₕᵣₑₛₕ 320 in this example. The corresponding output signal for this fixed-step method is shown as Vₒᵤₜ 335.

A C2V converter measures capacitance by counting the number of cycles (steps) required to reach Vₜₕᵣₑₛₕ. In the multi-phase embodiment, each coarse step can be counted as a number of cycles equal to the ratio of the step sizes. For example, if V_{step_large} is eight times V_{step_small}, each coarse step is counted as eight cycles. This ensures that the total “counted cycles” is roughly the same for both the variable-step and constant-step techniques, providing the same high resolution. For example, for a given capacitance, the constant-step technique might yield a count of 322 in 322 μs, while the variable-step technique could yield a nearly identical count of 321 in only 105 μs. This demonstrates how the multi-phase technique achieves a significant reduction in measurement time without sacrificing resolution.

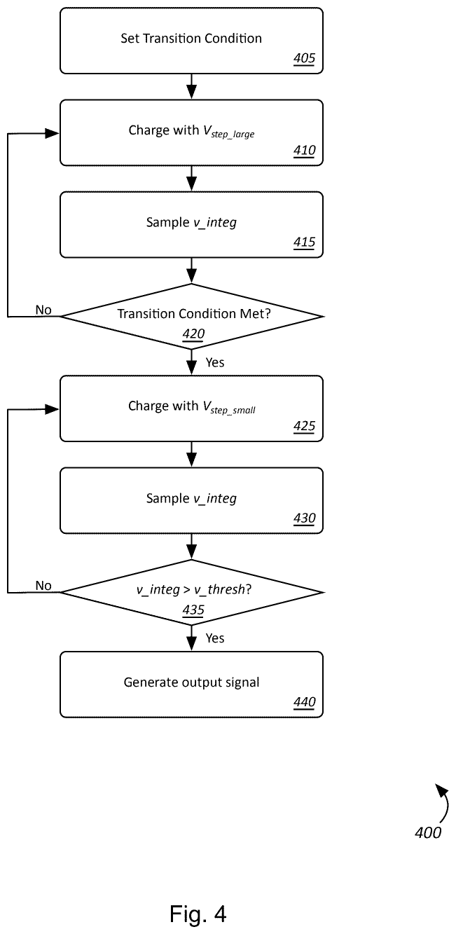

FIG. 4 is a flowchart illustrating a method 400 for determining HGA height using a multi-phase C2V converter, in accordance with some embodiments. The method 400 represents a single, complete measurement cycle that can be performed by a CHS circuit, such as the circuit 200 of FIG. 2A or the circuit 200′ of FIG. 2B, under the control of its respective control logic.

At block 405, the method 400 comprises setting a transition condition. In some embodiments, this operation can be performed by control logic, such as the control logic 280 shown in FIG. 2A, and establishes the point at which the measurement might switch from the coarse phase to the fine phase. This operation can involve the control logic 280 performing a brief initial measurement (e.g., using a single coarse voltage step), sampling the resulting integrated voltage, and extrapolating the total number of fine steps that will likely be needed to reach the final threshold. Based on this estimate, the control logic 280 can calculate a transition point, such as a specific cycle count. In other embodiments, the transition condition can be a predetermined voltage level, which can be referred to as a preliminary threshold, against which the integrated voltage is compared. A “preliminary threshold voltage” is used herein to refer to a voltage level used by the control logic to determine the transition point from a coarse measurement phase to a fine measurement phase.

At block 410, the method 400 comprises, in a coarse measurement phase of a measurement cycle, repeatedly charging a variable capacitor with a first voltage step. For example, control logic 280 can initiate this coarse measurement phase by controlling the variable voltage sources 270 and 275 to apply a large voltage step (V_{step_large}) across the variable capacitor 220. This can result in the steep slope for the integrated voltage seen in the coarse phase 310 of FIG. 3, allowing the voltage to ramp up quickly.

At block 415, the method 400 comprises integrating charge from the variable capacitor to generate a first portion of an integrated voltage. This integration can be performed by an integrator subcircuit, where charge transferred from the variable capacitor 220 is accumulated on a filter capacitor, such as the filter capacitor 255. During this coarse phase, the resulting integrated voltage (V_{integ}) at the output of an amplifier, such as the amplifier 225, can be sampled by the control logic 280.

At block 420, the method 400 comprises determining if the transition condition has been met. In some embodiments, the control logic 280 might perform this determination. This can involve comparing the sampled V_{integ} to a preliminary voltage threshold. Alternatively, the control logic 280 can determine if a predetermined number of charging cycles has elapsed. If the condition has not been met, the method can loop back to block 410 to continue charging with the coarse voltage step.

If the transition condition has been met, the method can proceed to block 425, where the method 400 comprises, in a fine measurement phase of the measurement cycle, repeatedly charging the variable capacitor with a second voltage step, wherein the second voltage step is smaller than the first voltage step. The control logic 280 can initiate this fine measurement phase by controlling the variable voltage sources 270 and 275 to apply the smaller voltage step (V_{step_small}). This corresponds to the shallower slope of the fine phase 315 shown in FIG. 3.

At block 430, the method 400 comprises integrating charge from the variable capacitor to generate a second portion of the integrated voltage. During the fine phase, the charge transferred during each cycle can again be accumulated on the filter capacitor 255, adding to the charge already accumulated during the coarse phase. The total integrated voltage (V_{integ}) can continue to be sampled by the control logic 280.

At block 435, the method 400 comprises determining if a final measurement condition has been met. This can involve a comparator, such as the comparator 260, comparing the total integrated voltage to a final threshold voltage (Vₜₕᵣₑₛₕ). If the integrated voltage has not yet exceeded the final threshold, the method can loop back to block 425 to continue charging with the fine voltage step.

At block 440, once the final condition is met (i.e., V_{integ}>Vₜₕᵣₑₛₕ), the method 400 comprises generating, based on the integrated voltage, an output signal indicative of a change in a height of the HGA relative to the media. In some embodiments, this output signal can be the binary output (Vₒᵤₜ) from the comparator 260, which indicates that the height threshold has been crossed. In other embodiments, the output signal can be a multi-bit digital value (DOUT) from an optional ADC, such as the ADC 265, which can provide a more granular measurement of the HGA's height.

In various embodiments, the method 400 can be reiterated to provide continuous or periodic measurements of the HGA height, with each full execution of the method generating a new output signal (e.g., a new Vₒᵤₜ or DOUT value) corresponding to a new height measurement.

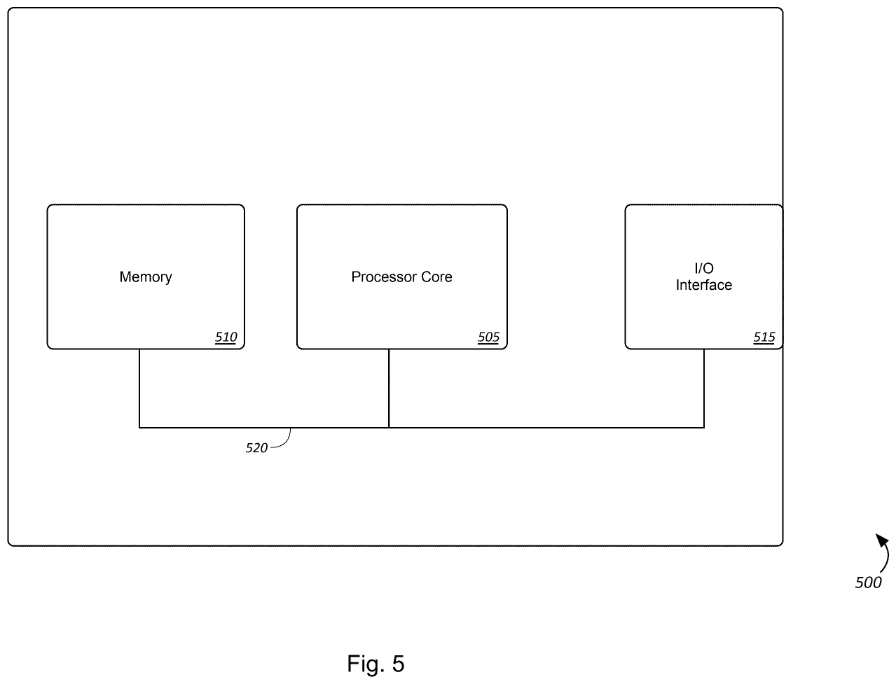

FIG. 5 is a block diagram illustrating an example of a controller 500 that can be used to implement the control logic described herein (e.g., control logic 110, 280). The controller 500 provides a hardware architecture that can execute software and/or firmware instructions to carry out the functions of a CHS circuit, such as those described above. It should be noted, however, that embodiments are not limited to those using the controller 500 or any controller at all. The controller 500 can include a processor core 505, a memory 510, an input/output (I/O) interface 515, and a bus or interconnect 520. The various components can communicate with each other via the bus 520. The processor core 505 can be a general-purpose processor, a microcontroller, a Digital Signal Processor (DSP), or any other suitable instruction-executing main processing unit configured to perform the methods described herein. The memory 510 can be a non-transitory computer-readable medium that stores instructions and/or data. For example, memory 510 can store the executable instructions that, when executed by the processor core 505, cause the controller 500 to perform the steps of the methods shown in the flowcharts. Memory 510 can also be used to store data during operation, such as prior reference counts, estimated target step counts for a C2V measurement, or other intermediate values. The I/O interface 515 can provide a communication interface between the processor core 505 and the other components of the system. For example, the I/O interface 515 can be configured to transmit control signals to the various switches, variable voltage sources, and measurement circuits described in the preceding figures. It can also be configured to receive measurement data, such as a digital output from an ADC or a final count from a TDC. In operation, the processor core 505 can execute instructions stored in the memory 510 to perform the methods and processes described herein.

### Further Examples

A set of embodiments provides methods. An exemplary method in accordance with some embodiments comprises, in a first phase of a measurement cycle, repeatedly charging a variable capacitor with a first voltage step and integrating charge from the variable capacitor to generate a first portion of an integrated voltage. In some embodiments, the method comprises, in a second phase of the measurement cycle, repeatedly charging the variable capacitor with a second voltage step, wherein the second voltage step is smaller than the first voltage step, and integrating charge from the variable capacitor to generate a second portion of the integrated voltage. In some embodiments, the method comprises generating, based on the integrated voltage, an output signal indicative of a change in a height of the HGA relative to the media.

In some embodiments, the method comprises transitioning from the first phase to the second phase when the integrated voltage exceeds a preliminary threshold voltage. In some embodiments, the method comprises transitioning from the first phase to the second phase after a predetermined number of charging cycles in the first phase. In some embodiments, the first voltage step is an integer multiple of the second voltage step.

In some embodiments, the method comprises increasing sensitivity of the charge-to-voltage converter by removing a fixed amount of charge from the variable capacitor using an offset circuit during each measurement cycle. In some embodiments, generating the output signal comprises comparing the integrated voltage to a final threshold voltage.

A set of embodiments provides apparatuses. An exemplary apparatus in accordance with some embodiments comprises a charge-to-voltage converter configured to generate an integrated voltage based on charge from a variable capacitor formed between a head gimbal assembly (HGA) and a media. In some embodiments, the apparatus comprises a variable voltage source configured to provide a charging voltage to the variable capacitor. In some embodiments, the apparatus comprises logic configured to control the variable voltage source to repeatedly charge the variable capacitor with a first voltage step during a first phase of a measurement cycle, and control the variable voltage source to repeatedly charge the variable capacitor with a second voltage step during a second phase of the measurement cycle, wherein the second voltage step is smaller than the first voltage step, and generate an output signal indicative of a change in a height of the HGA relative to the media based on the integrated voltage generated by the charge-to-voltage converter.

In some embodiments, the logic is configured to transition from the first phase to the second phase when the integrated voltage exceeds a preliminary threshold voltage. In some embodiments, the first voltage step is an integer multiple of the second voltage step. In some embodiments, the apparatus comprises an offset circuit configured to remove a fixed amount of charge from the variable capacitor during each charging cycle. In some embodiments, the apparatus comprises a comparator having a first input coupled to an output of the charge-to-voltage converter and a second input coupled to a final threshold voltage, the comparator configured to generate the output signal. In some embodiments, the apparatus comprises an analog-to-digital converter (ADC) configured to digitize the integrated voltage to generate the output signal. In some embodiments, the apparatus comprises logic to calibrate the output signal based on a measurement of a reference capacitor by substituting the reference capacitor for the variable capacitor.

In some embodiments, the charge-to-voltage converter comprises a first switch configured to be controlled by a first clock signal, the first switch comprising a first terminal and a second terminal, wherein the variable capacitor is coupled to the first terminal. In some embodiments, the charge-to-voltage converter comprises an amplifier comprising an inverting input, a noninverting input, and an output, wherein the inverting input is coupled to the second terminal of the first switch. In some embodiments, the charge-to-voltage converter comprises a filter capacitor coupled between the inverting input and the output of the amplifier.

A set of embodiments provides systems. An exemplary system in accordance with some embodiments comprises a head gimbal assembly (HGA) and a media, wherein a variable capacitance is formed between the HGA and the media. In some embodiments, the system comprises a circuit comprising a charge-to-voltage converter configured to generate an integrated voltage based on charge from the variable capacitance. In some embodiments, the circuit comprises a variable voltage source configured to provide a charging voltage to the variable capacitance. In some embodiments, the circuit comprises logic configured to control the variable voltage source to repeatedly charge the variable capacitor with a first voltage step during a first phase of a measurement cycle, and repeatedly charge the variable capacitor with a second voltage step during a second phase of the measurement cycle, wherein the second voltage step is smaller than the first voltage step, wherein the logic is further configured to generate an output signal indicative of a change in a height of the HGA relative to the media.

In some embodiments, the system comprises an offset circuit configured to remove a fixed amount of charge from the variable capacitance during each charging cycle. In some embodiments, the system comprises a comparator configured to compare the integrated voltage to a final threshold voltage to determine if the change in the height of the HGA exceeds a threshold distance. In some embodiments, the system comprises an analog-to-digital converter (ADC) configured to generate the output signal as a digital output corresponding to the height of the HGA.

### CONCLUSION

In the foregoing description, for the purposes of explanation and illustration, numerous details have been set forth to provide a thorough understanding of the described embodiments. It will be apparent to one skilled in the art, however, that other embodiments may be practiced without some of these specific details. In other instances, certain structures, devices, and techniques have been shown in block diagram form or simplified form to avoid unnecessarily obscuring the disclosure. Several embodiments are described herein, and while various features are ascribed to different embodiments, it should be appreciated that the features described with respect to one embodiment may be incorporated with other embodiments as well. By the same token, however, no single feature or features of any described embodiment should be considered essential to every embodiment, as other embodiments may omit such features.

It should be recognized that the systems, methods, and techniques described herein can be implemented in various forms and combinations. In some embodiments, the described functionality might be implemented primarily in software, while in other embodiments it might be implemented primarily in hardware or firmware. Still other embodiments might employ combinations of software, hardware, and/or firmware in varying proportions. The particular implementation chosen can depend on various factors including, without limitation, performance requirements, cost constraints, power consumption targets, available development resources, time-to-market pressures, regulatory requirements, and/or other design considerations.

Thus, the foregoing description provides illustration and description of various features and aspects of different embodiments but is not intended to be exhaustive or to limit the embodiments to the precise forms disclosed. One skilled in the art will recognize that modifications and variations can be made in light of the above disclosure and/or may be acquired from practice of the implementations, all of which can fall within the scope of various embodiments. For example, as noted above, the methods and processes described herein may be implemented using various combinations of software components, firmware components, and/or hardware components (including without limitation general-purpose processors, specialized processors, custom integrated circuits (ICs), programmable logic devices, accelerators, and/or other hardware circuitry), and/or any combination thereof.

Further, while various methods and processes described herein may be described with respect to particular structural and/or functional components for ease of description, methods provided by various embodiments are not limited to any particular structural and/or functional architecture. Instead, such methods can be implemented on any suitable hardware, firmware, and/or software configuration. Similarly, while certain functionality is ascribed to certain system components in the examples herein, unless the context dictates otherwise, this functionality can be distributed among various other system components in accordance with different embodiments. The distribution of functionality can be static or dynamic, potentially changing during system operation based on various factors.

Moreover, while the procedures of the methods and processes described herein are described in a particular order for ease of description, unless the context dictates otherwise, various procedures may be reordered, added, combined, split, and/or omitted in accordance with various embodiments. The order of operations shown in the figures should not be construed as limiting unless explicitly stated as required. Additionally, certain operations shown as sequential might be performed in parallel in some embodiments, while operations shown as parallel might be performed sequentially in others. The presence or absence of certain steps in the illustrated embodiments should not be construed as limiting the scope of the disclosure.

As used herein, the term “component” is intended to be broadly construed as hardware, firmware, software, or any combination thereof. It will be apparent that systems and/or methods described herein may be implemented in different forms of hardware, firmware, and/or combinations of hardware and software. The actual specialized control hardware or software code used to implement these systems and/or methods does not limit any embodiments unless specifically recited in the claims. Thus, the operation and behavior of the systems and/or methods have been described herein without reference to specific software code, with the understanding that software and hardware can be used to implement the systems and/or methods based on the description herein.

1. An apparatus, comprising:
a charge-to-voltage converter configured to generate an integrated voltage based on charge from a variable capacitor formed by capacitance between a head gimbal assembly (HGA) and a media;
a variable voltage source configured to provide a charging voltage to the variable capacitor; and
logic configured to:
control the variable voltage source to repeatedly charge the variable capacitor with a first voltage step during a first phase of a measurement cycle;
control the variable voltage source to repeatedly charge the variable capacitor with a second voltage step during a second phase of the measurement cycle, wherein the second voltage step is smaller than the first voltage step; and
generate an output signal indicative of a change in a height of the HGA relative to the media based on the integrated voltage generated by the charge-to-voltage converter.

2. The apparatus of claim 1, wherein the logic is configured to transition from the first phase to the second phase based on occurrence of a transition condition.

3. The apparatus of claim 1, wherein the first voltage step is an integer multiple of the second voltage step.

4. The apparatus of claim 1, further comprising an offset circuit configured to remove a fixed amount of charge from the variable capacitor during each charging cycle.

5. The apparatus of claim 1, further comprising a comparator having a first input coupled to an output of the charge-to-voltage converter and a second input coupled to a final threshold voltage, the comparator configured to generate the output signal.

6. The apparatus of claim 1, further comprising an analog-to-digital converter (ADC) configured to digitize the integrated voltage to generate the output signal.

7. The apparatus of claim 1, further comprising logic to calibrate the output signal based on a measurement of a reference capacitor by substituting the reference capacitor for the variable capacitor.

8. The apparatus of claim 1, wherein the charge-to-voltage converter comprises:
a first switch configured to be controlled by a first clock signal, the first switch comprising a first terminal and a second terminal, wherein the variable capacitor is coupled to the first terminal;
an amplifier comprising an inverting input, a noninverting input, and an output, wherein the inverting input is coupled to the second terminal of the first switch; and
a filter capacitor coupled between the inverting input and the output of the amplifier.

9. A method, comprising:
in a first phase of a measurement cycle:
repeatedly charging a variable capacitor with a first voltage step, wherein the variable capacitor is formed by capacitance between a head gimbal assembly (HGA) and a media; and
integrating charge from the variable capacitor to generate a first portion of an integrated voltage;
in a second phase of the measurement cycle:
repeatedly charging the variable capacitor with a second voltage step, wherein the second voltage step is smaller than the first voltage step; and
integrating charge from the variable capacitor to generate a second portion of the integrated voltage; and
generating, based on the integrated voltage, an output signal indicative of a change in a height of the HGA relative to the media.

10. The method of claim 9, further comprising transitioning from the first phase to the second phase based on occurrence of a transition condition.

11. The method of claim 10, wherein the transition condition comprises performance of a predetermined number of charging cycles in the first phase.

12. The method of claim 9, wherein the first voltage step is an integer multiple of the second voltage step.

13. The method of claim 9, further comprising increasing sensitivity of the charge-to-voltage converter by removing a fixed amount of charge from the variable capacitor using an offset circuit during each measurement cycle.

14. The method of claim 9, wherein generating the output signal comprises comparing the integrated voltage to a final threshold voltage.

15. The method of claim 9, further comprising calibrating the output signal based on a measurement of a reference capacitor by substituting the reference capacitor for the variable capacitor.

16. A system, comprising:
a head gimbal assembly (HGA) and a media, wherein a variable capacitor is formed by capacitance between the HGA and the media; and
a circuit, comprising:
a charge-to-voltage converter configured to generate an integrated voltage based on charge from the variable capacitor;
a variable voltage source configured to provide a charging voltage to the variable capacitor; and
logic configured to control the variable voltage source to:
repeatedly charge the variable capacitor with a first voltage step during a first phase of a measurement cycle;
repeatedly charge the variable capacitor with a second voltage step during a second phase of the measurement cycle, wherein the second voltage step is smaller than the first voltage step; and
generate an output signal indicative of a change in a height of the HGA relative to the media.

17. The system of claim 16, wherein the logic is configured to transition from the first phase to the second phase based on occurrence of a transition condition.

18. The system of claim 16, further comprising a comparator configured to compare the integrated voltage to a final threshold voltage to determine if the change in the height of the HGA exceeds a threshold distance.

19. The system of claim 16, further comprising an analog-to-digital converter (ADC) configured to generate the output signal as a digital output corresponding to the height of the HGA.

20. The system of claim 16, further comprising logic to calibrate the output signal based on a measurement of a reference capacitor by substituting the reference capacitor for the variable capacitor.
